(19) United States
(12) Patent Application Publication
(10) Pub. No.: US 2017/0098558 A1
(43) Pub. Date: Apr. 6, 2017

(54) ACID REPLENISHING SYSTEM AND METHOD FOR ACID TANK

(71) Applicant: United Microelectronics Corp., Hsinchu (TW)

(72) Inventors: Tzung-Wu Hou, Kaohsiung City (TW); Po-Lun Cheng, Kaohsiung City (TW); Meng-Che Yeh, Tainan City (TW); Feng-Nan Chu, Tainan City (TW)

(21) Appl. No.: 14/935,210

(22) Filed: Nov. 6, 2015

(30) Foreign Application Priority Data
Oct. 6, 2015 (TW) 104132781

(51) Int. Cl. H01L 21/67; C09K 13/04; C09K 13/08

(52) U.S. Cl. CPC H01L 21/67075; C09K 13/08; C09K 13/04

(57) ABSTRACT

An acid replenishing system includes an acid tank, a draining apparatus, an acid replenishing apparatus, and a control unit. The acid tank contains a used acid solution. The draining apparatus drains an amount of the used acid solution from the acid tank. The acid replenishing apparatus replenishes an amount of a replenishing acid into the acid tank. The control unit controls the draining apparatus and the acid replenishing apparatus to perform a plurality of acid replenishing stages, so a total set amount of the replenishing acid to be added into the acid tank has been replenished.

### CROSS-REFERENCE TO RELATED APPLICATION

This application claims the priority benefit of Taiwan application serial no. 104132781, filed on Oct. 6, 2015. The entirety of the above-mentioned patent application is hereby incorporated by reference herein and made a part of this specification.

### BACKGROUND OF THE INVENTION

1. Field of the Invention

The present invention generally relates to semiconductor equipment and, in particular, to an acid replenishing system and an acid replenishing method for acid tank.

2. Description of Related Art

In fabricating semiconductor device, it usually needs to perform wet etching process to remove a portion of dielectric material in the device as required during the fabrication process. The usual dielectric material is silicon oxide, silicon nitride, et al., as the example. The etchant of the wet etching process for the dielectric material contains acid, such as hydrofluoric acid (HF) or phosphoric acid (H₃PO₄), which is used to react with the dielectric material, thereby removing the dielectric material at the exposed portion.

When density of the semiconductor device is getting high, the size of the semiconductor device needs to be reduced. However, to achieve the device performance as needed, the dielectric material with relative high dielectric constant, such as silicon nitride, is chosen to replace the silicon oxide. The phosphoric acid is used to react with the silicon nitride to remove the silicon nitride at the contacted portion. The phosphoric acid would be consumed in the etching reaction and therefore needs to be replenished. In addition, if the reactants after reaction are still kept in the acid, it would affect the predetermined etching rate, so an amount of the reactants need to be drained to keep the acid concentration and contents in the acid tank.

After replenishing the acid into the acid tank, it usually needs to wait for a certain period of time to get to a stable condition for mixing of the acid in the acid tank, After then, it can be used the next batch. This waiting period of time would cause the increase of time cost. Therefore, how to reduce the waiting time for getting stable condition for acid mixing and thereby improve throughput, is at least one of the issues to be considered in development.

### SUMMARY OF THE INVENTION

The present invention is directed to acid replenishing system and method, in which a time to get to stable condition for acid mixing in the acid tank can be reduced.

The present invention provides an acid replenishing system including an acid tank, a draining apparatus, an acid replenishing apparatus, and a control unit. The acid tank contains a used acid solution. The draining apparatus drains an amount of the used acid solution from the acid tank. The acid replenishing apparatus replenishes an amount of a replenishing acid into the acid tank. The control unit controls the draining apparatus and the acid replenishing apparatus to perform a plurality of acid replenishing stages, so a total set amount of the replenishing acid to be added into the acid tank has been replenished.

In an embodiment of the invention, the acid replenishing system further includes a water replenishing apparatus, used to replenish an amount of water into the acid tank, wherein an evaporated amount of water in the acid tank is compensated.

In an embodiment of the invention of the foregoing acid replenishing system, the replenishing acid is hydrofluoric acid or phosphoric acid.

In an embodiment of the invention of the foregoing acid replenishing system, an operation temperature of the acid tank is higher than a temperature of the replenishing acid.

The present invention provides an acid replenishing method, used in an acid replenishing control for an acid tank after processing a batch of wafers. The acid tank containing a used acid solution. The method includes: estimating a predetermined replenishing amount of a replenishing acid to be replenished into the acid tank; and performing a plurality of replenishing stages to add the predetermined replenishing amount into the acid tank, wherein each of the replenishing stages drains an amount of the used acid solution form the acid tank and replenishes an amount of the predetermined replenishing amount into the acid tank.

In an embodiment of the invention of the foregoing acid replenishing method, the method further includes replenishing an amount of water into the acid tank by a water replenishing apparatus, to compensate an evaporated amount of water in the acid tank.

In an embodiment of the invention of the foregoing acid replenishing method, the replenishing acid is hydrofluoric acid or phosphoric acid.

In an embodiment of the invention of the foregoing acid replenishing method, an operation temperature of the acid tank is higher than a temperature of the replenishing acid.

The present invention provides an acid replenishing method, wherein an acid tank contains a used acid solution. The acid replenishing method includes: estimating a predetermined replenishing amount of a replenishing acid to be replenished into the acid tank; and performing a number of replenishing stages to add the predetermined replenishing amount into the acid tank, wherein the number is determined according to the predetermined replenishing amount and an operation temperature of the acid tank, the number is greater than or equal to 2. Each of the replenishing stages drains an amount of the used acid solution form the acid tank.

In an embodiment of the invention of the foregoing acid replenishing method, the method further includes replenishing an amount of water into the acid tank by a water replenishing apparatus, to compensate an evaporated amount of water in the acid tank.

In an embodiment of the invention of the foregoing acid replenishing method, the replenishing acid is hydrofluoric acid or phosphoric acid.

In an embodiment of the invention of the foregoing acid replenishing method, the operation temperature of the acid tank is higher than a temperature of the replenishing acid.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a drawing, schematically illustrating an acid replenishing system for acid tank to replenish acid, according to an embodiment of the invention.

FIG. 2 is a drawing, schematically illustrating an acid replenishing system for acid tank to replenish acid to acid tank, according to an embodiment of the invention.

FIG. 3 is a drawing, schematically illustrating an acid replenishing method to replenish acid to acid tank, according to an embodiment of the invention.

FIG. 4 is a drawing, schematically illustrating an acid replenishing method to replenish acid to acid tank, according to an embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

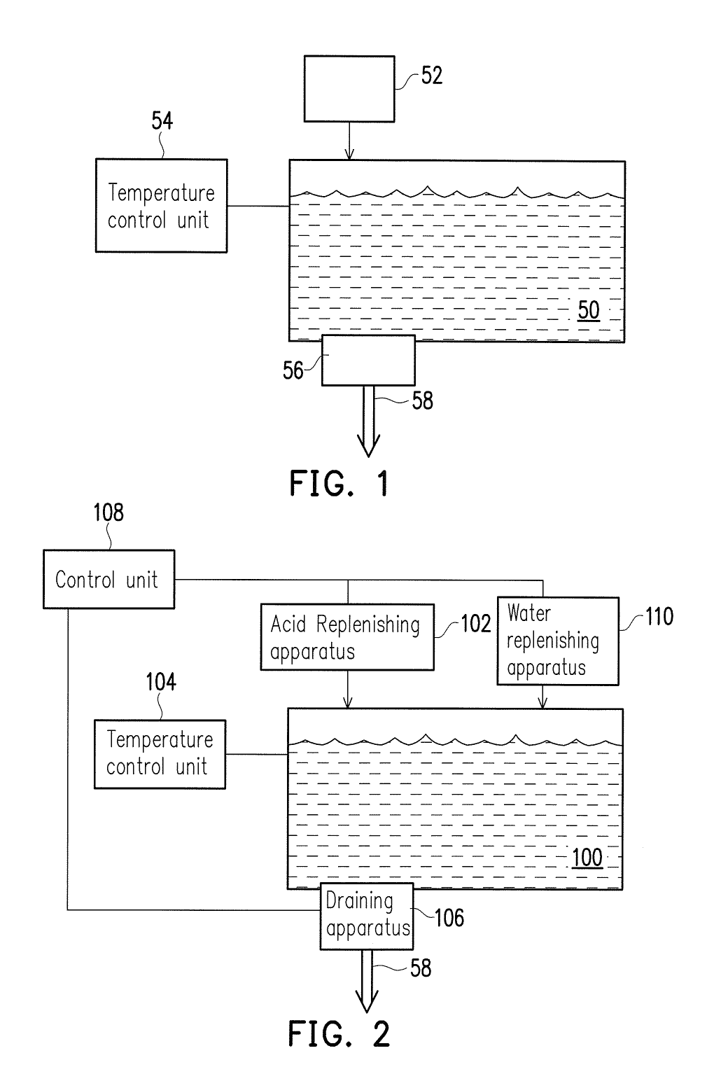

For the operation method in better detail, because the wet etching process usually consume a large amount of etchant, the acid needs to be replenished after the processing a batch in each time. FIG. 1 is a drawing, schematically illustrating an acid replenishing system for acid tank to replenish acid, according to an embodiment of the invention. Referring to FIG. 1, the acid tank 50 contains the used acid solution, which includes phosphoric acid and water. Before performing wet etching process, phosphoric acid is mixed with water to have the desired acid concentration. However, after wet etching process for one batch, the phosphoric acid reacts with silicon nitride and is consumed by a large amount, resulting in decreasing concentration of phosphoric acid and affecting the etching rate. Thus, phosphoric acid needs to be replenished after the etching process is performed for one batch.

One-time acid replenishing process uses a draining apparatus 56 to perform one-time draining, that is, a fix amount of the used acid solution 58 is drained out from the acid tank 50 in one time of draining. The acid in the acid tank 50 having been consumed can be replenished by the acid replenishing apparatus 52 to replenish a fix amount of acid, such as phosphoric acid, into the acid tank 50. Thus, the action to replenish the acid can be accomplished by one-time process.

Further, the operation temperature of the acid tank 50 in a range of 130° C.-180° C. in an example, or 155° C. in an example, is higher than the temperature of the replenishing acid, such as in a range of 80° C.-120° C. in an example or 100° C. in an example. The temperature control unit 54 is then used to control and maintain the temperature of the acid tank 50.

After the acid in the acid tank 50 is replenished in one-time process, it needs to wait for a certain period of time to get to the stable condition for acid mixing. After then, the acid solution in the acid tank 50 can be used by the next batch of wafers to perform the same etching process.

As to the acid replenishing mechanism in FIG. 1, it needs to wait for a certain long period of time to get to the stable condition for acid mixing. The invention has looked into the acid replenishing mechanism and found one of the possible reasons. Taking the phosphoric acid tank as an example, its operation temperature is about 155° C. in an example. The one-time draining process would drain a rather large amount of the used acid solution at high temperature from the acid tank in one-time draining, and then a large amount of thermal energy id taken out from the acid tank. However, the temperature of the replenishing acid being added is for example at 100° C., which is far lower than the operation temperature. A large degree of temperature difference exits between them. Further, in order to compensate the evaporated amount of water, some water is also needed to replenish. The temperature of water is in a range of 10° C.-75° C. in an example, in which 25° C. in an example is the usual temperature. The temperature difference between the replenishing acid and the acid tank may cause unstable thermal flow in the acid tank. It then needs a long period of time to get to the stable condition for acid mixing.

In other words, the temperatures of the replenishing acid and the water may be lower than ⅓ of the operation temperature. The acid mixing would be unstable after adding the replenishing acid into the acid tank. Although the temperature control unit 54 would heat the acid tank, the acid replenished into the acid tank still needs a long period of time to get to stable mixing because the thermal loss in the whole acid tank is still significantly large. For example, it would take 45 minutes to get to the stable mixing at the operation temperature of the acid tank.

The invention further provides the replenishing mechanism with multiple stages, which can reduce the need of time to get to stable condition of acid mixing in the acid replenishing process after one batch of wafers. Multiple embodiments are provided for description but not for restricting the invention.

The acid in the acid tank decreases due to consumption of fabrication process, such as etching process, which consumes the acid used for etching. An acid replenishing process is needed after each batch of wafers under operation in the acid tank, in which a predetermined replenishing amount of a replenishing acid is replenished. The invention can control the acid replenishing process in the acid tank with respect to the predetermined replenishing amount as required, so the acid mixing can be accelerated and the needed time to get to the stable mixing can be reduced.

In the acid replenishing process of the embodiment of the invention, the predetermined replenishing amount is not replenished in one time but multiple replenishing stages are taken. In each of replenishing stages only drains an amount of the used acid solution and adding an amount of the replenishing acid as intended. Thus, after the multiple replenishing stages, the multiple amounts of the replenishing acid being added reaches to the predetermined replenishing amount.

Here, the invention is not limited to sequence of draining the used acid solution first and then replenishing the acid next, or replenishing the acid first and then draining the used acid solution next. However, to easily control the predetermined replenishing amount, usually, it takes draining the used acid solution first and then replenishing the acid next.

Since the temperature of the acid tank is higher than the temperature of the replenishing acid to be added, it can avoid the serious thermal loss caused by draining a large amount of the used acid solution at relatively high temperature in one time because only an amount of the used acid solution is drained out from the acid tank and an amount of replenishing acid is also added into the acid tank in each of replenishing stages. Since only a small amount of the used acid solution is drained out from the acid tank in each replenishing stage, the temperature of the acid tank is still close to the operation temperature expected by the acid tank, and the thermal apparatus can also easily recover the temperature of the acid tank. The replenishing acid under the temperature relatively close to the operation temperature of the acid tank can be easier to mix to get to the stable mixing.

The decision of the number of the replenishing stages is related to the consideration on the wager count and the operation time of the acid tank. Table 1 is an embodiment to estimate the number of the replenishing stages according to the expected throughput.

TABLE 1

| | | Wafer count in one batch | | | |
|---|---|---|---|---|---|
| | | 50~40 | 40~30 | 30~20 | <20 |
| Operation time (sec) of | 3000 | 40 | 32 | 23 | 0 |
| H₃PO₄ in the acid tank/ | 2400 | 34.5 | 23 | 17.5 | 0 |
| draining time (sec) | 2000 | 28 | 19 | 14 | 0 |

The operation time of draining in each time being 15 seconds is taken as as an example and the wafer count is 45 in one batch. From table 1, the needed draining time is 40 seconds. Then, 40 seconds is divided by 15 seconds for each draining and obtain 2.66 times, which is 3 times of draining. The number of replenishing stages is then 3. However, Table 1 is just an embodiment and the estimation of number of replenishing stages in actual operation is not just limited to table 1.

FIG. 2 is a drawing, schematically illustrating an acid replenishing system for acid tank to replenish acid, according to an embodiment of the invention. Referring to FIG. 2, the acid replenishing system for acid tank in an example includes an acid tank 100, a draining apparatus 106, a replenishing apparatus 102, and a control unit 108. The acid tank 100 contains a used acid solution. The used acid solution contains the acid not consumed yet, such as phosphoric acid or hydrofluoric acid, and further contains residual reactant due to the chemical reaction after use of acid, and further contains water for adjusting the concentration.

The draining apparatus 106 is used to drain an amount of the used acid solution 58 from the acid tank 100. The replenishing apparatus 102 is used to add an amount of the replenishing acid, such as phosphoric acid or hydrofluoric acid. The control unit 108 controls the draining apparatus 106 and the replenishing apparatus 102 to perform a plurality of replenishing stages, so a total set amount of the replenishing acid to be added into the acid tank has been replenished.

In other words, the amount of the used acid solution being drained out and the amount of the replenishing acid being added in each replenishing stage is just a small amount with respect to the predetermined replenishing amount. So, a small amount of the used acid solution 58 at high temperature id drained out from the acid tank 100, and a small amount of the replenishing acid is correspondingly added into the acid tank 100. Then a significant thermal loss would not occur on the acid tank 100 and the replenishing acid being replenished can easily get to mix. The temperature control unit 104 can also heat the acid tank 100 in faster speed to maintain at the operation temperature. After the operation of multiple replenishing stages with small amount, the replenishing acid being added into the acid tank 100 can get to the stable mix in faster speed. After the comparison in experiment, the time of 45 minutes can be reduced to 15 minutes in an example.

For the multiple replenishing stages to the acid tank, the number of stages for draining acid is depending on the acid amount to be replenished and also the consideration to maintain the acid tank to the operation temperature as much as possible for helping the acid mix. The number of stages can for example be 10 stages, or such 5-15 stages. However in general, the number of stages is at least taking 2 stages.

Here, because a small amount of the newly replenished acid may be drained in each time of draining acid, the actual amount of the replenishing acid being added may be more than the total expected amount. As to the number of the replenishing stages, a table data, such as Table 1, may be build up for reference, according to theoretic estimation. In addition, the replenishing amount in each stage and the number of replenishing stages can also be determined according to the measuring data from a simulating operation or a real operation. In other words, after generally considering the related factor and the need, the number of replenishing stages and the replenishing amount can be determined, so the time needed for mixing acid can be reduced.

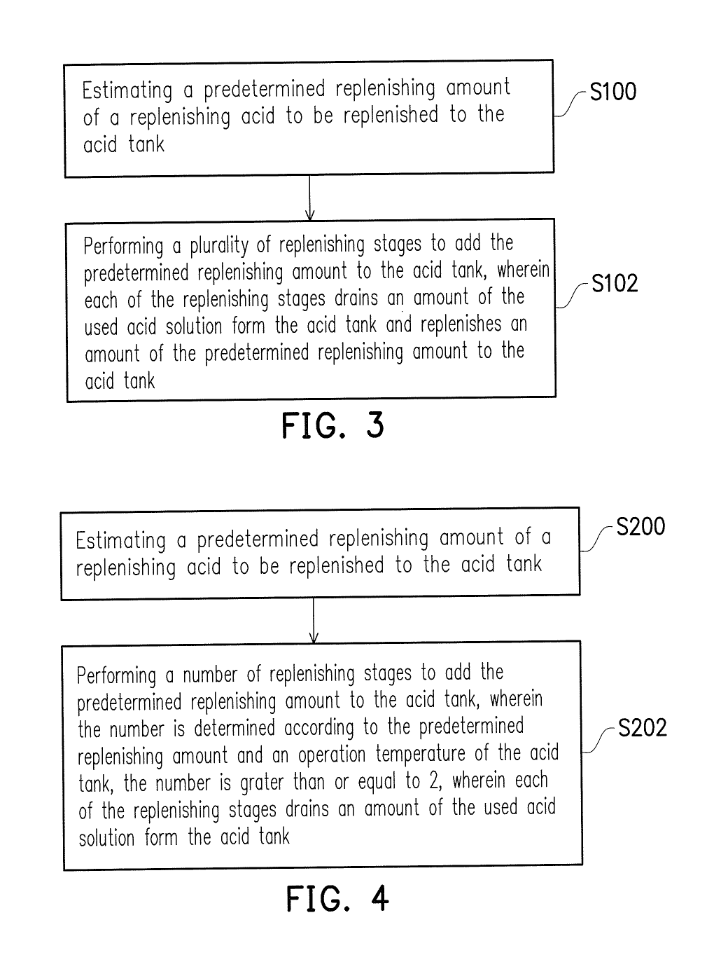

FIG. 3 is a drawing, schematically illustrating an acid replenishing method to replenish acid to acid tank, according to an embodiment of the invention. Referring to FIG. 3, in operation, the acid replenishing method of the invention can include step S100, which estimates a predetermined replenishing amount of a replenishing acid to be replenished to the acid tank. In step S102, a plurality of replenishing stages is performed to add the predetermined replenishing amount to the acid tank, wherein each of the replenishing stages drains an amount of the used acid solution form the acid tank and replenishes an amount of the predetermined replenishing amount to the acid tank.

FIG. 4 is a drawing, schematically illustrating an acid replenishing method to replenish acid to acid tank, according to an embodiment of the invention. Referring to FIG. 4, in operation, the acid replenishing method of the invention can include step S200, which estimating a predetermined replenishing amount of a replenishing acid to be replenished to the acid tank. In step S202, a number of replenishing stages are performed to add the predetermined replenishing amount to the acid tank, wherein the number is determined according to the predetermined replenishing amount and an operation temperature of the acid tank, the number is greater than or equal to 2, wherein each of the replenishing stages drains an amount of the used acid solution form the acid tank.

The invention may have more significant effect for the fabrication process with lager consumption of acid, such as the case that the phosphoric acid is used to remove the silicon nitride of the semiconductor structure or the hydrofluoric acid is used to remove the silicon oxide of the semiconductor structure.

The replenishing phosphoric acid in the invention can maintain the concentration of silicon ions, so the etching rate to the oxide can also be maintained. It can reduce the variation in the batches for the thickness of oxide layer on the surface of the structure.

Further, because the water in the actual fabrication process, such as etching process, would be evaporated and the concentration would be changed. Thus, when the acid is replenished and the acid concentration needs to be controlled, the water can be added in multiple stages, accordingly. Depending on actual need, this is also a further feature of the invention.

As to foregoing descriptions, the invention takes multiple acid replenishing stages to replenish the acid to the acid tank at high temperature, so the acid can be mixed in faster speed. The waiting time between the batches can be reduced, and the throughput can be improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An acid replenishing system, comprising:
an acid tank, containing a used acid solution;
a draining apparatus, draining an amount of the used acid solution from the acid tank;
an acid replenishing apparatus, replenishing an amount of a replenishing acid into the acid tank; and
a control unit, controlling the draining apparatus and the acid replenishing apparatus to perform a plurality of acid replenishing stages, so a total set amount of the replenishing acid to be added into the acid tank has been replenished.

2. The acid replenishing system of claim 1, further comprising a water replenishing apparatus, used to replenish an amount of water into the acid tank, wherein an evaporated amount of water in the acid tank is compensated.

3. The acid replenishing system of claim 1, wherein the replenishing acid is hydrofluoric acid or phosphoric acid.

4. The acid replenishing system of claim 1, wherein an operation temperature of the acid tank is higher than a temperature of the replenishing acid.

5. An acid replenishing method, used in an acid replenishing control for an acid tank after processing a batch of wafers, the acid tank containing a used acid solution, comprising:
estimating a predetermined replenishing amount of a replenishing acid to be replenished into the acid tank; and
performing a plurality of replenishing stages to add the predetermined replenishing amount into the acid tank, wherein each of the replenishing stages drains an amount of the used acid solution form the acid tank and replenishes an amount of the predetermined replenishing amount into the acid tank.

6. The acid replenishing method of claim 5, further comprising replenishing an amount of water into the acid tank by a water replenishing apparatus, to compensate an evaporated amount of water in the acid tank.

7. The acid replenishing method of claim 5, wherein the replenishing acid is hydrofluoric acid or phosphoric acid.

8. The acid replenishing method of claim 5, wherein an operation temperature of the acid tank is higher than a temperature of the replenishing acid.

9. An acid replenishing method, wherein an acid tank contains a used acid solution, the acid replenishing method comprising:
estimating a predetermined replenishing amount of a replenishing acid to be replenished into the acid tank; and
performing a number of replenishing stages to add the predetermined replenishing amount into the acid tank, wherein the number is determined according to the predetermined replenishing amount and an operation temperature of the acid tank, the number is greater than or equal to 2, wherein each of the replenishing stages drains an amount of the used acid solution form the acid tank.

10. The acid replenishing method of claim 9, further comprising replenishing an amount of water into the acid tank by a water replenishing apparatus, to compensate an evaporated amount of water in the acid tank.

11. The acid replenishing method of claim 9, the replenishing acid is hydrofluoric acid or phosphoric acid.

12. The acid replenishing method of claim 9, wherein the operation temperature of the acid tank is higher than a temperature of the replenishing acid.
